(19) United States
(12) Patent Application Publication
(10) Pub. No.: US 2004/0145874 A1
(43) Pub. Date: Jul. 29, 2004

(54) Method, system, and apparatus for embedding circuits

(76) Inventors: Stephane Pinel, Atlanta, GA (US); Joy Laskar, Atlanta, GA (US)

Correspondence Address: TROUTMAN SANDERS LLP, BANK OF AMERICA PLAZA, SUITE 5200, 600 PEACHTREE STREET , NE, ATLANTA, GA, 30308-2216, US

(21) Appl. No.: 10/735,480

(22) Filed: Dec. 12, 2003

Related U.S. Application Data
(60) Provisional application No. 60/441,952, filed on Jan. 23, 2003.

(51) Int. Cl. H05K 7/02

(52) U.S. Cl. 361/748

(57) ABSTRACT

A method, system, and apparatus for embedding circuits. The present invention allows reduction in the size of fabricated multichip modules by embedding circuitry within a substrate. A first layer of dielectric material is provided and a circuit having a predetermined length, width, and depth is provided. Then, a cavity is formed in the first layer of dielectric material substantially corresponding to the predetermined length and width of the circuit. After the cavity is formed, the circuit is deposited into the cavity. Once the circuit is deposited, a second layer of dielectric material may be provided to cover the circuit.

### CROSSS REFERENCE TO RELATED APPLICATION AND CLAIM OF BENEFIT

This application is based on and claims the priority date of U.S. Provisional Application Ser. No. 60/441,952, filed on Jan. 23, 2003, which is incorporated by reference in its entirety as if fully set forth herein.

### TECHNICAL FIELD

The invention relates generally to the field of chip fabrication and, more specifically, to the field of ultra-compact multi-chip module fabrication.

### BACKGROUND OF THE INVENTION

As the world has become more reliant on electronic devices, and portable electronic devices, the desire for smaller and faster devices has increased. Accordingly, producers of such devices strive to create faster and smaller devices to serve the consumer's needs.

Recent developments in advanced packaging technologies, such as 3D multi-chip modules, provide an opportunity for significant reduction in mass, volume and power consumption. Simultaneously, emerging wireless communications applications in the RF/microwave/millimeter wave regimes require miniaturization, portability, cost and performance as key driving forces in the electronics packaging evolution. The System-on-Package (SOP) approach (versus the System-On-Chip, SOC) for module development is presently a popular approach for systems integration due to the real estate efficiency, cost-savings, size reduction and performance improvement potentially associated with this approach. However current RF module integration is still based on low density hybrid assembly technologies. Embedded IC technology is targeted for low cost RF applications and provides great opportunities for ultra-compact integrated RF front-end module.

The development of wireless data communication systems in various frequency bands leads to very stringent specifications for both IC and packaging performances. For these portable and low-powered applications, a high level of integration and high performances materials are required. Due to the large number of high performance discrete passive components, RF front-end module integration is very challenging. Many examples of implementations onto ceramic substrates have been reported. Accordingly, a problem in the prior art is that circuit modules consume too much space. Another problem in the art is that circuits can not be embedded within a substrate in a simple, reliable manner. Another problem in the art is that commercially produced chip sets can not be embedded within a substrate in a space conserving manner.

These and various other features as well as advantages, which characterize the present invention, will be apparent from a reading of the following detailed description and a review of the associated drawings.

### SUMMARY

In accordance with the present invention, the above and other problems are solved by a method, system, and apparatus for embedding circuits. The present invention allows reduction in the size of fabricated multichip modules by embedding circuitry within a substrate. A cavity substantially equal to the dimensions of the circuit is formed into the substrate and the circuit is inserted into the cavity. The cavity is then covered by an additional layer of substrate dielectric material thereby embedding the circuit within the substrate.

In accordance with other aspects, the present invention relates to a method for embedding a circuit in a substrate. According to the method, a first layer of dielectric material is provided and a circuit having a predetermined length, width, and depth is provided. Then, a cavity is formed in the first layer of dielectric material substantially corresponding to the predetermined length, width and depth of the circuit. After the cavity is formed, the circuit is deposited into the cavity. Once the circuit is deposited, a second layer of dielectric material is preferably provided to cover the circuit.

These and various other features as well as advantages, which characterize the present invention, will be apparent from a reading of the following detailed description and a review of the associated drawings.

### BRIEF DESCRIPTION OF THE DRAWINGS

FIG. 1 is an illustration of an embedded circuit fabrication process in accordance with an exemplary embodiment of the present invention.

FIG. 2 is a flow diagram depicting an embedded circuit fabrication process according to an exemplary embodiment of the present invention.

FIG. 3 is an illustration of a high density embedded circuit according to an exemplary embodiment of the present invention.

FIG. 4 is an illustration of an embedded circuit according to an exemplary embodiment of the present invention.

### DETAILED DESCRIPTION OF THE INVENTION

Referring now to the drawings, in which like numerals represent like elements, exemplary embodiments of the present invention will be described.

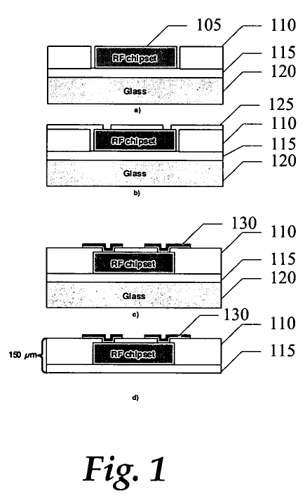

FIG. 1 is an illustration of an embedded circuit fabrication process in accordance with an exemplary embodiment of the present invention. As shown in FIG. 1, a circuit may be embedded within a substrate and directly interconnected to other components. Such a circuit may be an RF chipset, a processor, or any other circuit desired to be mounted within a circuit board or substrate. This configuration promotes efficient space consumption as the circuitry is directly embedded into the board or substrate rather than being mounted onto the surface of the board or substrate. Additionally, in an exemplary embodiment of the present invention, the circuit is used without an accompanying package. For example, and not limitation, typical integrated circuits (ICs) are encased in a packaging material such as plastic, ceramic, or the like. When the circuit is embedded within a circuit board or substrate, such packaging material is unnecessary. Accordingly, the space consumed by such a package is eliminated and the overall dimension of the finished product may be greatly reduced.

While the present invention is generally directed toward embedding a circuit within a circuit board or substrate, an exemplary embodiment of the present invention is described in which the circuit is embedded using a modified multi-chip module deposition (MCM-D) process. Those skilled in the art will appreciate that circuits may be embedded using other methods, such as standard MCM-D or MCM-L techniques.

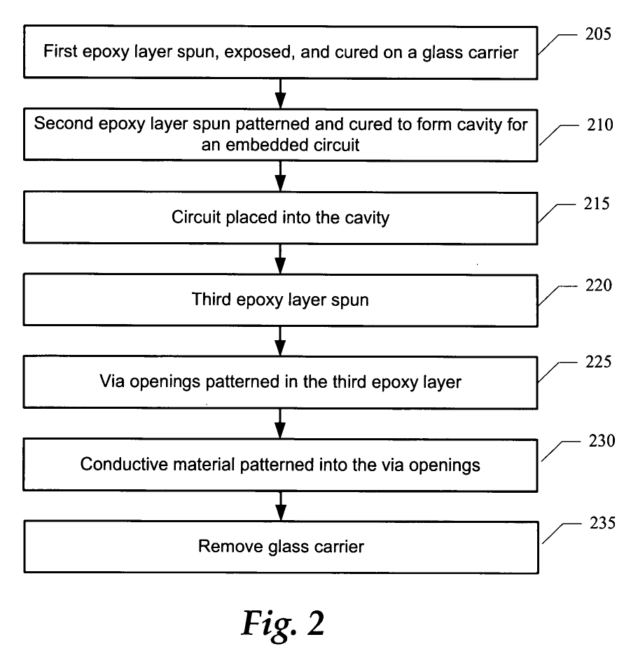

FIG. 2 is a flow diagram depicting an embedded circuit fabrication process according to an exemplary embodiment of the present invention. FIGS. 1a through 1d illustrate intermediate states of an embedded circuit during fabrication. FIGS. 1 and 2 will be discussed together as an exemplary fabrication process is described. Those skilled in the art will appreciate that other fabrication methods are available using various materials. An exemplary embodiment of the present invention utilizes a photosensitive epoxy for fabrication. Photosensitive epoxy, such as INTERVIA™, may be patterned using a mask and an ultraviolet light. Such materials do not require the use of high heat or corrosive materials in order to be patterned for vias and cavities. While not necessary, it may be desirable to use such materials because high heat or corrosive materials may adversely affect the embedded circuit if the circuit is sensitive to such factors. Alternatively, other materials or processes may be used, however many prefabricated circuits desired to be embedded may not tolerate heat or corrosion.

In accordance with an exemplary embodiment of the present invention, a glass wafer 120 may be used as a carrier for the module fabrication. The carrier provides a base upon which other layers may be fabricated. Alternatively, any suitable carrier may be used. Typically, the first step involves spinning, exposing and curing a first epoxy layer 115 on the glass carrier 120 (step 205). In an exemplary embodiment, the first epoxy layer 115 is approximately 33 μm thick. The thickness of the epoxy layer is not critical and those skilled in the art will appreciate the various factors involved in selecting the various layer thicknesses. Those skilled in the art are familiar with spinning a substrate to build up a thickness of the substrate on a carrier. In such a process the speed and duration of the spin correlates to the resultant thickness. After the substrate is spun, it is exposed to an ultraviolet light. A mask may be used to define vias or cavities in the substrate. After the substrate is exposed, it is cured (step 205).

Next, a second epoxy layer 110 is spun, patterned, and cured to form a cavity for the embedded circuit 105 (step 210). It is preferable that the thickness of this epoxy layer be the same as the circuit's thickness. Such a configuration enables good planarization (step 225). Generally, the process involves placing a layer of epoxy on the preceding layer (either glass carrier or epoxy layer), planarizing the layer, placing a mask on the layer representative of the pattern desired to be present on the layer, exposing the layer to ultraviolet light to produce the desired pattern, and curing the layer. Generally, it is desirable for the dimensions of the cavity to substantially correlate to the dimensions of the circuit 105 to be embedded (i.e., length, width, and depth approximately equal). However, it may be desirable for the cavity to be larger than the circuit 105 to promote easy insertion of the circuit 105 into the cavity. In an exemplary embodiment of the present invention, the second epoxy layer is approximately 75 μm thick. In an exemplary embodiment of the present invention, the thickness of the second epoxy layer is approximately equal to the thickness of the circuit to be embedded. For best results, the second epoxy layer should be equal in thickness to the circuit. Extended curing time may be needed to fully polymerize the thick epoxy layer.

Next, the circuit 105 may be placed into the cavity (step 215). In an exemplary embodiment of the present invention, an RF chipset is used as the embedded circuit. Alternatively, any desired circuit may be embedded. While any chipset may be used, it may be preferable to use a chipset without its usual casing in order to minimize the thickness of the module. FIG. 1a shows the embedded circuit 105 positioned in the cavity created in the second epoxy layer 110. If the cavity is properly dimensioned, the circuit 105 may easily self-align itself. It may be desirable to use a hot plate at approximately 90° C. to promote temporal adhesion of the circuit 105 to the epoxy 115, 110. Next, a third epoxy layer 125 is spun and planarized to embed the circuit. In an exemplary embodiment of the present invention, the third epoxy layer 125 is approximately 20 μm thick. After the layer is spun, a mask is used to pattern via openings in the third layer 105 using a photolithography process (step 225).

Next, a thin layer of conductive material 130 is deposited to contact the embedded circuit (step 230). In an exemplary embodiment of the present invention, a 3 μm thick Ti/Cu/Ti metal layer is sputtered and patterned to contact the embedded circuit. Alternatively, other metals or conductive materials may be used to connect the circuit 105. Also, metallization deposited by electroplating techniques may improve the metal continuity at the connection pad. Good metal contact with the circuit pads and adhesion to the dielectric promote reliable performance. Therefore, the via openings are typically cleaned and the dielectric surfaces roughened to significantly increase peel strength by means of Reactive Ion Etching (RIE) before the sputtering of the metal. Finally, the glass carrier 120 is removed (step 235). In order to remove the glass carrier, the module may be protected with black wax. Then, the glass carrier is selectively etched in a HF solution to produce the module shown in FIG. 1d. The total thickness of the module, in the illustrated example, is less than 150 μm. The step of removing to glass carrier 120 (step 235) reduces the thickness of the module and provides a more compact finished unit.

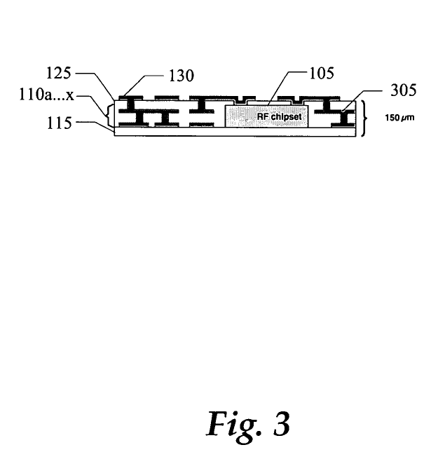

FIG. 3 is an illustration of a high density embedded circuit according to an exemplary embodiment of the present invention. As shown in FIG. 3, vias may be embedded within the second layer of epoxy adjacent to the embedded circuit to increase the density of the finished module. In an exemplary embodiment of the present invention, vias 305 may be embedded through a multilayer fabrication approach. Rather than spinning a thick second epoxy layer 110 as described in conjunction with FIGS. 1 and 2, the second layer 110 may consist of a plurality of sub-layers. In such a configuration, a sequence of thin sub-layers is spun in succession to build up to the thickness of the earlier described thick second layer 110. In this process of spinning successive intermediate layers, one may create a cavity in an intermediate layer and fill the cavity with conductive material to form a via or a trace. This process is identical to the process described in conjunction with layer three in FIG. 1. Additionally, as each intermediate layer is spun, the cavity for the embedded circuit 105 is created. Upon completion of all of the intermediate layers, a cavity large enough to embed the circuit is preserved.

In order to create a uniformly dimensioned cavity for the circuit 105, it may be desirable to use a sacrificial fill in intermediate cavities. In such a process, after the cavity is formed in each successive sub-layer, the cavity is filled with a metal or other removable material. After all of the sublayers are created, the metal fill may be etched away to reform the cavity. If another removable material is used, it may be removed using an appropriate procedure. While not necessary for forming a uniform cavity through the multiple sublayers, the metal fill may make the repeated spinning and planarizing procedure more consistent and yield better results.

In an exemplary embodiment of the present invention, a microwave multi-layer interconnect structure may be built on a glass carrier using modified MCM-D technology and advanced photosensitive epoxy. In accordance with the embodiment illustrated in FIG. 3, a low loss interconnect may be fabricated using a build-up technology and approximately 9 to 12 μm thick electroplated copper. Those skilled in the art will appreciate that the thickness of the 9 to 12 μm electroplated copper is provided for example only, and is not intended to limit the present invention. Micro-via technology with an approximate diameter of 40 μm may be used to connect the different metal layers. Thus a high density interconnect network and integral passive components such as high performances embedded inductors, filters and antennas may be implemented within the multi-layer wiring structure

In the exemplary embodiment illustrated in FIG. 3, an RF commercial chipset is placed into the cavity created in the MCM-D process and covered by a dielectric layer. The cavity provides self-alignment for the chipset with the interconnection structure. Furthermore, the process may be used to embed and planarize commercial dies or circuits of 3 mils to 4 mils thick, or even thicker. The outer metal layer may used to connect the embedded circuit and final contact pads may be covered with thin Ni/Au.

This approach avoids parasitics due to wire bonding, flip-chip or BGA type of interconnection and parasitic interconnection length between the active circuitry and the passives components is greatly reduced. Furthermore, the glass carrier substrate used during the fabrication may be selectively etched and removed, leading to volume and weight reduction. The use of commercial bare die in the module fabrication leads to high fabrication yield and solves KGD (Known Good Die) issues associated with other embedding techniques.

While those skilled in the art are familiar with various procedures for layering epoxy, an exemplary process for producing an exemplary embodiment of the present invention using Intervia™ 8000 is provided. This exemplary process is provided for example only, and is not intended to limit the scope of the present invention. An exemplary embodiment of the present invention may include different thicknesses of epoxy layers, such as 20, 33 and 75 μm. In order to achieve such thicknesses, spin-coating rotation speed may be set from approximately 800 to 2500 rpm. After spinning the Intervia™ 8000 may be processed as follows:

Soft bake at 90° C. for 30 minutes in a convection oven;

Expose dose of 1300 mJ/cm using i line; (those skilled in the art will recognize that i line refers to 365 nm UV light)

Post-bake at 80° C. for 30 minutes in a convection oven;

Develop in RDP1014 (100%) bath at 35-40° C. for 2-3 min;

Semi-cure at 130° C. for 30 minutes in a convection oven; and

Complete curing is performed, if it is needed, at 190°C. for 60 minutes in a convection oven.

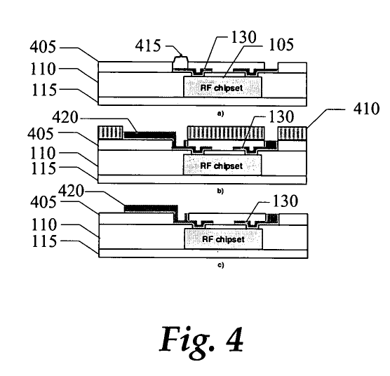

FIG. 4 is an illustration of an embedded circuit according to an exemplary embodiment of the present invention. FIG. 4 provides additional layers above the module shown in FIG. 1. These additional layers may be fabricated according to the following process:

An additional 33 μm thick dielectric layer 405 is spun and micro-vias 415 are created using photolithography (FIG. 4a);

A thin metal Ti/Cu/Ti layer 410 is sputtered to act as a seed layer;

20 μm thick photo-resist is spun and patterned;

Electroplating of copper 420 at an approximate rate of 4 μm per 30 min to get a copper layer thickness of 13 μm (FIG. 4b).

Stripping the photo-resist and etching off the seed layer 410 at the rate of approximately 1 μm per minute and therefore lead to final copper features 420 of approximately 12 μm thick (FIG. 4c).

The additional layers may be used for signal lines. Alternatively, the procedure shown in FIG. 2 may be repeated and a second circuit may be embedded above the first circuit.

While this invention has been described in detail with particular reference to exemplary embodiments thereof, it will be understood that variations and modifications may be effected within the scope of the invention as defined in the appended claims.

We claim:

1. A method of embedding a circuit, comprising the steps of:
providing a first layer of dielectric material;
providing a circuit having a predetermined length, width, and depth;
forming a cavity in the first layer of dielectric material substantially corresponding to the predetermined length and width of the circuit; and
depositing the circuit into the cavity.

2. The method of claim 1, wherein the step of providing the first layer of dielectric material comprises forming a layer of dielectric material at least as thick as the depth of the circuit.

3. The method of claim 1, further comprising the steps of:
providing a carrier and
wherein said step of providing a first layer of dielectric material comprises depositing the dielectric material on the carrier.

4. The method of claim 3, wherein said carrier is glass.

5. The method of claim 1, wherein the dielectric material is a photosensitive epoxy.

6. A method of embedding a circuit, comprising the steps of:
providing a carrier;
providing a first layer of dielectric material;
providing a circuit having a predetermined length, width, and depth;
providing a second layer of dielectric material;
forming a cavity in the second layer of dielectric material corresponding to the predetermined length and width of the circuit;
depositing the circuit into the cavity; and
providing a third layer of dielectric material.

7. The method of claim 6, wherein the circuit has one or more connection points and further comprising the steps of:
forming via openings in the third layer at positions substantially corresponding to each of the connection points of the circuit; and
providing conductive material in the via openings.

8. The method of claim 6, wherein the step of providing a second layer of dielectric material comprises providing a plurality of sub-layers of dielectric material.

9. The method of claim 8, wherein the step of providing a plurality of second layers of dielectric material comprises:
providing a first sub-layer of dielectric material;
forming a first cavity in the first sub-layer of dielectric material substantially corresponding to the predetermined length and width of the circuit;
forming one or more via openings in the first dielectric sub-layer;
providing conductive material in the via openings of the first sub-layer of dielectric material;
providing a second sub-layer of dielectric material;
forming a second cavity in the second sub-layer of dielectric material substantially corresponding to the predetermined length and width of the circuit and in a position substantially corresponding to the first cavity formed in the first sub-layer of dielectric material;
forming one or more via openings in the second dielectric sub-layer; and
providing conductive material in the via openings of the second sub-layer of dielectric material.

10. The method of claim 9, further comprising the steps of:
providing a sacrificial material in the first cavity;
providing a sacrificial material in the second cavity; and
removing the sacrificial material from the first and second cavity.

11. An embedded circuit module comprising:
a first layer of dielectric material;
a circuit having a predetermined length, width, and depth;
a cavity in the first layer of dielectric material substantially corresponding to the predetermined length and width of the circuit; and
wherein the circuit is embedded in the cavity.

12. The module of claim 11, wherein the first layer of dielectric material is at least as thick as the depth of the circuit.

13. The module of claim 11, wherein the dielectric material is a photosensitive epoxy.

14. An embedded circuit module, comprising:
a first layer of dielectric material;
a circuit having a predetermined length, width, and depth;
a second layer of dielectric material deposited upon the first layer of dielectric material;
a cavity in the second layer of dielectric material substantially corresponding to the predetermined length and width of the circuit;
a third layer of dielectric material deposited upon the second layer of dielectric material; and
wherein the circuit is embedded in the cavity in the second layer of dielectric material.
